(19) United States
(12) Patent Application Publication
(10) Pub. No.: US 2026/0040463 A1
(43) Pub. Date: Feb. 5, 2026

(54) Microelectronic Packaging Using Circuits on Glass and Stacking Glass Circuits

(71) Applicant: Sciperio, Inc, Orlando, FL (US)

(72) Inventors: Kenneth H. Church, Orlando, FL (US); Samuel LeBlanc, Orlando, FL (US)

(73) Assignee: Sciperio, Inc, Orlando, FL (US)

(21) Appl. No.: 19/287,329

(22) Filed: Jul. 31, 2025

Related U.S. Application Data
(60) Provisional application No. 63/679,416, filed on Aug. 5, 2024.

(51) Int. Cl. H05K 3/36; H05K 1/14; H05K 3/32

(52) U.S. Cl. CPC H05K 3/368; H05K 1/144; H05K 3/321; H05K 2201/035; H05K 2201/042; H05K 2203/1131

(57) ABSTRACT

A method for creating and stacking glass substrates containing conductive lines, vias, and passive components to form high-density, three-dimensional microelectronic packages. The invention employs a conductive nanoparticle paste for bonding, with silver nanopaste offering significant advantages in terms of process temperature and stability. The method includes precise control mechanisms for separation thickness, edge sealing, outgassing control, vacuum sealing, connector integration, and real-time data collection using IoT sensors. These innovations enable the creation of complex 3D structures with tight tolerance, high reliability, and suitability for electronics, photonics and including RF applications and other high-frequency applications.

### RELATED APPLICATIONS

This application claims priority to U.S. Provisional Patent Application No. 63/679,416, filed Aug. 5, 2024, hereby incorporated by reference in its entirety.

### FIELD OF THE INVENTION

The present disclosure relates to microelectronic packaging, more particularly, but not exclusively, methods and devices involving glass or ceramic substrates with conductive lines, vias, and passive components, which may be stacked to form complex three-dimensional circuits.

### BACKGROUND OF THE INVENTION

Traditional microelectronic packaging typically uses silicon, FR4, or ceramic substrates and various interconnect methods. Glass substrates offer advantages such as excellent thermal stability, electrical insulation, smooth surfaces, and the ability to be patterned with fine conductive features. Stacking multiple glass or ceramic circuits enhances the density and functionality of electronic devices but requires precise alignment and reliable electrical connections.

Achieving precise alignment and reliable electrical connections is a significant problem particularly in the context of stacked substrates. What is needed is microelectronic packaging which uses circuits on glass and allows for stacking glass circuits.

### SUMMARY

Therefore, it is a primary object, feature, or advantage to improve over the state of the art.

It is a further object, feature, or advantage to provide microelectronic packaging using glass or ceramic substrates.

It is a still further object, feature, or advantage to provide for stacking multiple glass or ceramic circuits to enhance density and functionality of electronic devices.

Another object, feature, or advantage is to provide precise alignment and reliable electrical connections.

It is a further object, feature, or advantage to provide a method for fabricating high-density microelectronic packages.

Another object, feature, or advantage is to use glass substrates for their superior thermal stability.

It is a further object, feature, or advantage to use ceramic substrates for enhanced electrical insulation.

Another object, feature, or advantage is to allow for fine conductive pattern formation on substrates.

It is a further object, feature, or advantage to provide a method for precise alignment of stacked substrates.

Another object, feature, or advantage is to use conductive nanoparticle paste for reliable electrical connections.

It is a further object, feature, or advantage to utilize nanopaste such as silver nanopaste for its low sintering temperature.

Another object, feature, or advantage is to avoid the reflow issues associated with traditional solder paste.

It is a further object, feature, or advantage to maintain substrate integrity during multiple sintering cycles.

Another object, feature, or advantage is to enable complex three-dimensional circuit formations.

It is a further object, feature, or advantage to control separation thickness between substrates with precision.

Another object, feature, or advantage is to integrate passive components into the substrates.

It is a further object, feature, or advantage to use laser micromachining for precise pit formation.

Another object, feature, or advantage is to provide glass or ceramic beads for separation control.

It is a further object, feature, or advantage to seal substrate edges for enhanced mechanical stability.

Another object, feature, or advantage is to allow outgassing during the sintering process.

It is a further object, feature, or advantage to apply a vacuum for hermetic sealing.

Another object, feature, or advantage is to integrate bulk connectors with dielectric adhesive.

It is a further object, feature, or advantage to collect real-time data during the manufacturing process.

Another object, feature, or advantage is to use IoT sensors for monitoring process parameters.

It is a further object, feature, or advantage to generate a digital twin for precise modeling and tracking.

Another object, feature, or advantage is to employ directed energy for sintering without an oven.

It is a further object, feature, or advantage to pattern nanopaste onto metallized and non-metallized areas.

Another object, feature, or advantage is to provide a method for stacking substrates without damaging previous layers.

It is a further object, feature, or advantage to improve the functionality of electronic devices.

Another object, feature, or advantage is to use polymers in nanopaste that burnout during heating for clean sintering.

It is a further object, feature, or advantage to reduce the overall manufacturing complexity.

Another object, feature, or advantage is to provide a scalable method for microelectronic packaging.

It is a further object, feature, or advantage to allow for the integration of active components with nanopaste.

Another object, feature, or advantage is to create vias using laser drilling and nanopaste filling.

It is a further object, feature, or advantage to facilitate the assembly of microelectronic packages using pick and place machines.

Another object, feature, or advantage is to achieve high precision in patterning conductive materials.

It is a further object, feature, or advantage to provide a method that is adaptable to various electronic applications.

Another object, feature, or advantage is to offer a cost-effective solution for advanced microelectronic packaging.

One or more of these and or other objects, features, or advantages will become apparent from the specification and claims that follow. No single embodiment need to provide each and every object, feature, or advantage as different embodiments may have different objects, features, or advantages.

The present disclosure provides a method for creating and stacking glass circuits that contain conductive lines, vias, and passive components. Each glass or ceramic circuit substrate can be a few hundred microns to a millimeter thick and range from a few millimeters to tens of centimeters in size. The stacking method may use conductive nanoparticle paste to electrically and mechanically bond the substrates.

The present disclosure provides a method for fabricating a microelectronic package using glass or ceramic substrates. This method involves providing a plurality of substrates, where each substrate is either a glass or ceramic substrate. A conductive nanoparticle paste is applied to at least one of the top surface of a first substrate or the bottom surface of a second substrate. The first and second substrates are then stacked such that the top surface of the first substrate bonds with the bottom surface of the second substrate, forming a stack. The conductive nanoparticle paste is then sintered to provide both electrical and mechanical bonding between the substrates.

Each substrate may contain conductive pads, lines, vias, and passive components. The nanoparticle paste used has a viscosity of at least 5,000 cP, typically within a range of 5,000 cP to 5,000,000 cP. In some embodiments, the nanoparticle paste has a viscosity of at least 10,000 cP, typically within a range of 10,000 cP to 1,000,000 cP. The stacking process ensures precise alignment of the substrates. Additional substrates can be added to the stack, with the nanoparticle paste applied to the surfaces to be bonded, and the process of stacking and sintering repeated. When using silver nanoparticles in the nanopaste, heating the stack sinters the silver, forming a pure silver interface.

Laser-micromachining may be employed to create pits in the substrates, which are then filled with glass or ceramic beads to control separation thickness. The nanoparticle paste may be applied to both metallized and non-metallized areas to assist in bonding and maintaining separation between substrates. The stacking is performed using a pick and place machine, which applies heat and pressure, ensuring precise alignment and bonding.

Edges of the substrates can be sealed using nanoparticle paste or ceramic paste for enhanced mechanical stability. Outgassing during sintering can be managed by creating holes in the substrates, applying a vacuum, sealing the holes in the vacuum, and heating to provide a hermetic seal. Directed energy, rather than an oven, can be used for sintering.

The method also includes integrating bulk connectors by printing or patterning nanopaste onto pads and adding dielectric adhesive for mechanical stability. Sensors can be used to acquire real-time data on temperature, humidity, air quality, and vibration, which can be analyzed for real-time evaluation. Additionally, a digital twin of the microelectronic package can be generated using this data.

This method of fabricating microelectronic packages using glass or ceramic substrates with conductive nanoparticle paste enables the creation of high-density, three-dimensional circuits with precise alignment, reliable electrical connections, and enhanced mechanical stability.

### BRIEF DESCRIPTION OF THE DRAWINGS

FIG. 1 illustrates a glass or ceramic substrate with metallized areas, precision microdispensed dots and lines of conductive nanopaste, and spacers in the form of glass or ceramic beads or microdispensed and sintered nanopaste.

FIG. 2 illustrates a bottom substrate and a top substrate, both patterned with conductive material, which are to be stacked.

FIG. 3 shows the operation of a pick and place machine used to align and stack the top substrate onto the bottom substrate with precision, applying pressure and heat.

FIG. 4 depicts the placement of active and passive components onto the top substrate using conductive nanopaste as a replacement for traditional solder.

FIG. 5 provides an overview of the manufacturing process, including steps of microdispensing nanopaste, stacking substrates, sintering, and repeating the process for additional substrates within a stack.

### DETAILED DESCRIPTION

The present disclosure relates to microelectronic packaging using circuits on glass or ceramic substrates and stacking the substrates. Although various embodiments are discussed it is to be understood that aspects of different embodiments may be combined.

Of particular interest here is the use of nano paste which is a composition which includes nano particles and especially conductive nano particles such as metallic nano particles. Given the thickness obtainable with nanopaste, it may hold shape similar to solder paste, yet does not have the same issues associated with solder paste. One benefit of using nano paste is once it is heated to a sintering temperature it is converted to near solid metal where the nano particles include metal nano particles. This is significant because if heated again, the deposited material does not melt because it is metal with a melting point higher than the sintering temperature. For example, the melting point of silver is around 962 degrees Celsius which is higher than the sintering temperature for silver nanopaste.

Thus for example, if one uses silver nano paste which sinters around 250 degrees Celsius (this will vary based on particle size) and then heats the resulting deposited silver material to 600 degrees Celsius, it does not melt. This is highly advantageous when used with stacking glass or ceramic substrates as such substrates may be stacked, sintered, stacked, sintered, etc. many times without damaging previously formed layers of substrate.

Compare this to solder paste which reflows. With solder paste if layers are stacked and reflow temperature is applied, the device can shift thus ruining or otherwise adversely affecting the circuit.

The nanopaste comprises nanoparticles, such as conductive nanoparticles, such as metallic nanoparticle such as silver nanoparticles. In addition, to including nanoparticles, nanopaste has a viscosity which is higher than inks or liquids. For example, the nanoparticle paste may have a viscosity of at least 10,000 cP and typically within a range of between about 10,000 cP and 1,000,000 cP. In addition to the nanoparticles, the paste may include polymers which may burnout when heated.

In comparison to nanopaste, nanoink is very runny and can only provide a thin layer of material which does not maintain its shape whereas nanopaste is very thick and thus provides a substantial number of options. Nanopaste is in some respects like solder paste in that it is thick and can retain its shape. For example, nanopaste may be used to hold the shape of a line which is 100 microns wide and 50 microns tall. Or nanopaste may be used to hold the shape of a dot that is 100 microns in diameter and 50 microns tall. Nanopaste can be used to make lines or dots which are 100 microns in X and/or Y dimensions while being only 25 microns tall.

Where a nano paste is used any number of different layers may be used. Moreover, each additional sintering step does not have an adverse effect on previous steps. This allows for precise alignment and reliable electrical connections to be maintained.

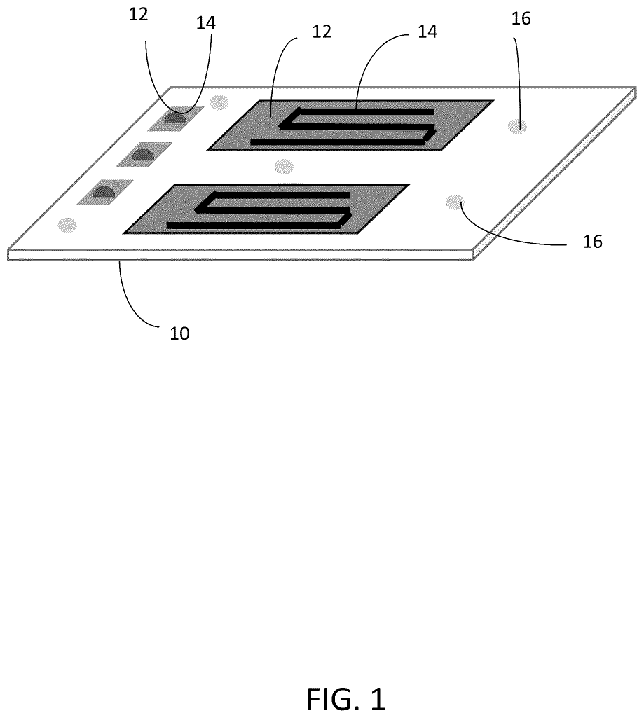

FIG. 1 illustrates one example of a glass or ceramic substrate 10 which may form the bottom substrate within a stack of substrates. As shown in FIG. 1, there are metallized areas 12 on the substrate. These metallized areas 12 may include pads or other areas. Although different types of metals may be used, one type of metal which may be used is gold to allow for excellent conductivity and without oxidizing or corroding over time and temperature. Elements or features 14 such as precision microdispensed dots and line of conductive nanopaste are shown. Also shown are spacers 16 in the form of glass or ceramic beads or microdispensed and sintered nano paste.

Glass or ceramic substrates are used instead of traditional silicon, FR4, or ceramic substrates. Glass substrates are advantageous over silicon, FR4, and ceramic substrates in various ways which may be important to a particular application. For example, glass substrates may provide excellent thermal stability, electrical insulation, smooth surface and the ability to be patterned with fine conductive features. The substrate may be a high quality glass or ceramic with a thickness from about a few hundred microns to about a millimeter. The X and Y dimensions for the substrate (when the substrate is planar) may be from a few millimeters to tens of centimeters.

The glass or ceramic substrate may be patterned with the elements or features such as with conductive lines, vias, and passive components such as resistors, capacitors, and inductors. Methods such as photolithography, etching, or other suitable microfabrication techniques may be used.

Conductive lines and vias or other features may be formed from highly conductive metals such as copper, gold, or silver. Pads are also formed. Pads are positioned to align precisely with pads on other substrates during stacking. The passive components may be integrated into the substrate through additional patterning processes.

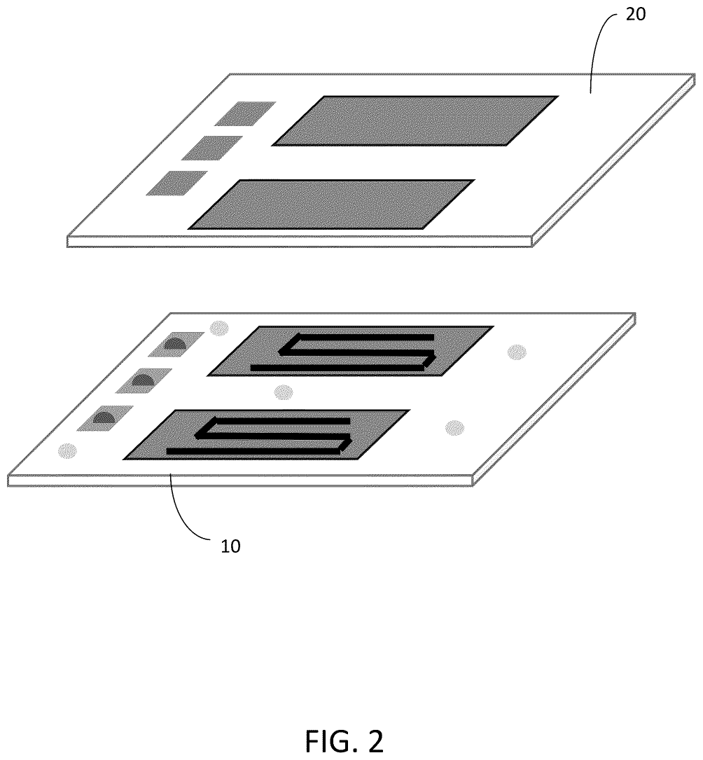

FIG. 2 further illustrates both the substrate 10 which may form a bottom substrate and a second substrate or top substrate 20. It is to be understood that the bottom substrate 10 and the top substrate 20 may be stacked. The top substrate 20 may also be a glass or ceramic substrate and may be patterned with conductive material on the bottom of the substrate 10.

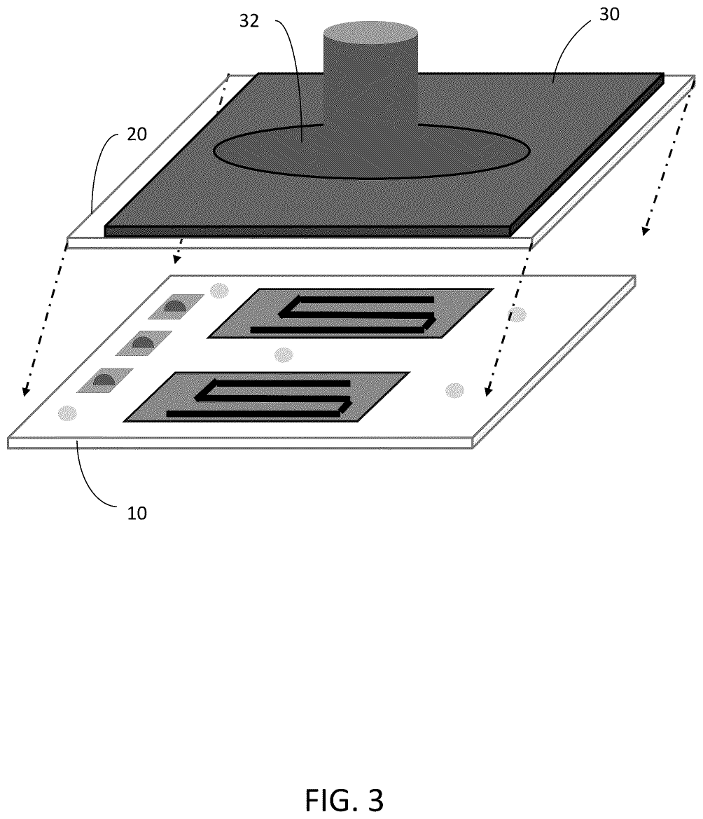

As shown in FIG. 3, in operation a pick and place machine may be used to pick and place the top substrate 20 onto the bottom substrate 10. The pick and place machine may include a plate 30 which used to apply pressure. The pick and place machine may have a pressure sensor so that pressure may be applied according to a pressure parameter. The pick and place machine provides for precision alignment between the top substrate 20 and the bottom substrate 10 and applying a set pressure.

Heating may be applied to the lower end of the pick and place machine to apply heat and pressure on the substrate to increase production speed and provide a reliable and repeatable process.

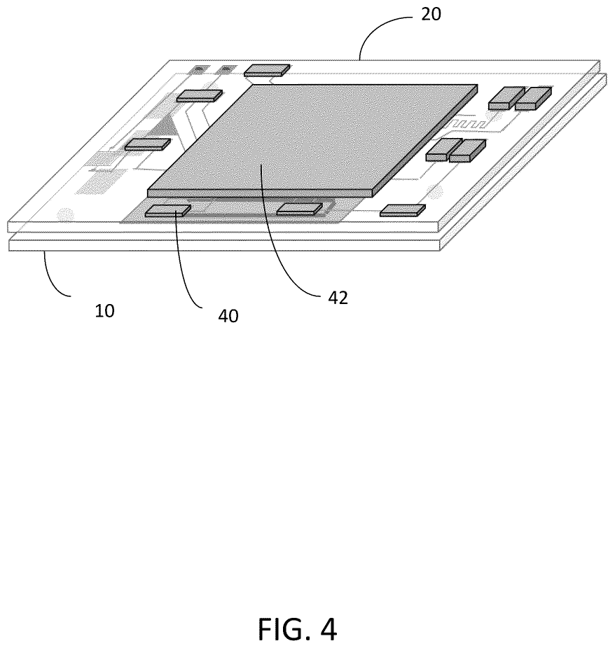

As shown in FIG. 4, active and passive components may also be packed and placed onto the top substrate using conductive nanopaste as a replacement of traditional solder. As previously explained, using a nanopaste where conductive nano particles are present allows for a sintering temperature less than the melting temperature of the conductive material. Thus, this is advantageous over the use of solder as connecting active and passive components using conductive nanopaste by sintering does not require temperatures which will affect the metal on the previous layers.

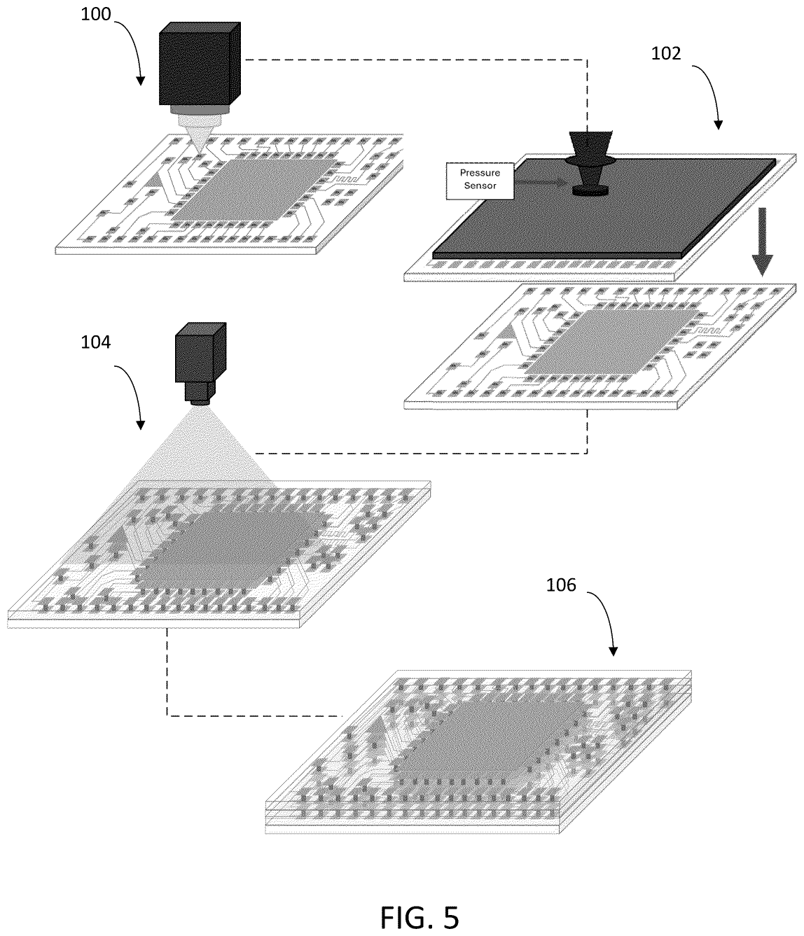

FIG. 5 provides an overview of a process for manufacturing. In step 100, nanopaste dots or lines or other patterns are microdispensed on a bottom substrate. Next, in step 102, a top substrate or top layer is picked and placed onto the bottom substrate with extreme precision to allow for proper alignment between features of the bottom substrate and features of the top substrate. Next In step 104, this dual layer (top substrate and bottom substrate) are heated in an oven or using an in situ infrared (IR) or laser heater for nanopaste sintering. Next as shown in step 106, the process may be repeated for additional substrates within a stack of substrates or additional layers. Each layer may be patterned using any number of techniques to place a metal pattern. The metallized substrate may contain pads or patterns that match or mirror an additional substrate. Nanopaste may be microdispensed on a bottom portion and then a top substrate is placed and then heated in an oven or otherwise. This can be repeated any number of times so that one layer or substrate overlays another layer or substrate as many times as needed to provide a desired stack. Each stack may be fired and this promotes a sold and rigid connection that holds even with multiple firings. This is advantageous over using solder as solder reflows can shift while the nanopaste does not reflow or shift.

More generally, a processor includes in step 100 application of nanopaste onto pads or lines of a first glass or ceramic substrate. The nanopaste may be printed or may be otherwise patterned. Next in step 102, alignment and placement is performed such as by precisely picking and placing a second glass or ceramic substrate on top of the first glass or ceramic substrate to provide exact alignment of the pads. Then in step 104, heating is performed to sinter the conductive nanoparticles such as silver nanoparticles within the nano paste. This process burns off the polymer carrier leaving pure silver (for example) as the electrical and mechanical interface. Then in step 106, the process may be repeated any number of times depending upon the desired number of layers of substrate within the stack.

As has previously been discussed use of nanopaste is advantageous. In some embodiments silver nanopaste may be especially advantageous. For example, there is no need for an oxygen-reduced environment due to silver's resistance to oxidation. In addition, silver provides excellent adhesion to gold, copper, and other metals. Silver nanopaste with silver nanoparticles has a lower sintering temperature (around 250 degrees Celsius) compared to micron-sized particles (>800 degrees Celsius). Moreover, post-sintering, the pure silver can withstand high temperatures without degradation allowing for multiple stacking cycles while still maintaining precision alignment.

This multi-layer stacking is significant as it allows for sequential stacking. After sintering each layer, additional layers may be added without disturbing the previous layers. This multi-layer stacking is also highly stable. Sintered silver, for example, ensures the stability and precise alignment of each layer, preventing minor shifts that could render the device inoperable. Moreover, the process is not limited by the number of substrate layers but allows for virtually unlimited stacking beyond the limitations of traditional solder reflow methods.

According to another aspect, separation thickness control may be provided. Precise control of the separation thickness between stacked glass or ceramic substrates may be critical in certain applications such as RF applications.

One method of obtaining separation thickness control is through laser micromachining strategic pits into the glass or ceramic substrates at specified locations. Then beads may be placed into the laser-machined pits. The beads may be glass or ceramic beads ranging from around 10 to around 100 microns in diameter. The beads may be picked and placed into the laser-machined pits. The pits maintain the beads in place and the beads have a diameter greater than the depth of the pits so that the beads provide for separation. Where silver nanopaste is used, the silver nanopaste may be printed or patterned onto the conductive pads of the substrate. Then a second glass or ceramic substrate may be precisely aligned and placed on to a first substrate in a manner which ensures that the pads align and the beads maintain separation. The second glass or ceramic substrate may be pressed to the first glass or ceramic substrate. The compression of the nanopaste during this pressing step ensures that the separation between substrates is tightly controlled. Moreover, this method maintains the necessary dielectric properties and mechanical stability required for RF applications.

When using the beads, the glass or ceramic beads may be dabbed with an adhesive to hold the beads in place within the laser-machined pits. This application of an adhesive helps ensure stability and precision during the stacking process.

Another method for controlling thickness is to print nanopaste dots, such as silver nanopaste dots and sinter them such that the dots acts as spacers. Thus, printed dots (not on pads, but strategically placed on the substrate) are sintered. Then dots and lines may be printed on pads and ground planes. Then pick and place and press steps may be performed with another substrate until it touches the sintered dots on the substrate it is overlaid upon. Thus a constant Z thickness may be obtained.

According to another aspect, the edges of the substrates may be sealed. After stacking, the edges of the substrates may be sealed using nanosilver paste or ceramic paste. The paste is patterned along the outer edges and heated to provide mechanical strength and stability to the stack.

In some embodiments outgassing control may be provided through use of strategically placed holes. These holes may be placed in the glass or ceramic substrates to allow outgassing of trapped polymers during the heating process thereby ensuring that any residual materials can escape and thereby preventing defects in the final product.

Hermetic sealing such as vacuum sealing may be applied. A vacuum may be pulled on the device and the top layer holes may be sealed while the device is under vacuum. Covering or filling the holes with ceramic paste and then heating then seals the holes, providing a hermetic seal with no trapped gas inside the multi-stack substrate.

Another advantage of the methods shown and described is that connectors may also be integrated into the multi-stack substrate. Nanopaste such as silver nanopaste may be printed or patterned onto the pads that aligns with the connector. Dielectric adhesive may be applied to provide mechanical stability. The adhesive may be applied prior to or during a heating process.

In some embodiments a high-temperature ceramic adhesive may be used. The ceramic-based adhesive may have a low process temperature but a high working temperature and may be used to add mechanical stability and thermal endurance.

The process of manufacturing may be performed where a plurality of sensors are used to provide data which may be used for monitoring the manufacturing process or controlling the manufacturing process. Real-time data collection may be performed using sensors for temperature, humidity, air quality, and vibration. The sensors may be IoT sensors. In some embodiments an algorithm may be used to ensure quality and identify any issues during stacking and post-processing. Thus sensor fusion or other algorithms may be used to optimize the quality of the stacking process or resulting device. In other embodiments, a digital twin of the device is constructed. In other words, through real-time data collection during the manufacturing of a specific device, a digital model of that specific device may be generated. This digital twin may be used in modeling the behavior of the specific device and is especially useful in high precision applications including in RF applications. Thus, instead of or in addition to manufacturing according to particular design tolerances, actual data from the manufacturing process of the specific device is used to model and predict behavior of the actual device.

One type of feature which may be created is vias. In some embodiments, vias may be created. For example, a laser may be used to dill holes within a substrate. The holes may then be filled with metal nanopaste and sintered in order to make vias.

In some embodiments, using nanopaste the plain glass or ceramic substrates may be patterned with the nanopaste and then sintered in order to add patterned metallization.

In some embodiments, ceramic paste may be used to add layers to the glass or ceramic substrates to further build up layers.

Throughout this detailed description, the use of relative terms such as “first,” “second,” “top,” “bottom,” “upper,” “lower,” “above,” “below,” “horizontal,” “vertical,” “inner,” “outer,” “front,” and “back” are for convenience and descriptive purposes only. These terms should not be construed as limiting the scope of the invention or excluding alternative configurations, orientations, or relative relationships between the described elements. The relative positions and orientations are used to facilitate the description of the present invention and can vary depending on the specific application or environment in which the invention is utilized.

Similarly, references to directions such as “X,” “Y,” and “Z” are intended to describe spatial orientations relative to each other and are not to be interpreted as restrictive or limiting. The invention can be practiced in various orientations and spatial arrangements without departing from the spirit and scope of the disclosed embodiments.

Similarly, references to paste and does not preclude it from being anything except a higher viscosity than standard inks. Clay, putty or other viscous material terminologies may be considered in the fabrication process.

Any relative terminology used herein is for explanatory purposes and should not be interpreted as restrictive. The invention encompasses various modifications, alternative configurations, and variations that fall within the scope of the appended claims and their equivalents.

Although specific embodiments and features have been shown and described, it is to be understood that any number of combinations, options, and variations are contemplated including variations in the nanoparticle paste including type of nanoparticles and size of nanoparticles, the viscosity of the nanoparticle paste and other options. Unless specifically claimed, the type of materials used, including the type of substrate, the type of material used in creating vias, the type of material used on the edges, the number of substrate layers within a stack, the specific sensors used for monitoring the process, and other variations, options, and alternatives.

1. A method for fabricating a microelectronic package using glass or ceramic substrates, the method comprising:
providing a plurality of substrates, wherein each of the plurality of substrates is one of a glass substrate and a ceramic substrate;
applying a first amount of a conductive nanoparticle paste on at least one of a top surface of a first of the plurality of substrates and a bottom surface of a second of the plurality of substrates;
stacking the first of the plurality of substrates and the second of the plurality of substrates such that the top surface of the first of the plurality of substrates is positioned to bond with the bottom surface of the second of the plurality of substrates to form a stack; and
sintering the first amount of the conductive nanoparticle paste to provide both electrical and mechanical bonding between the first of the plurality of substrates and the second of the plurality of substrates.

2. The method of claim 1 wherein each of the plurality of substrates contains at least one of conductive pads, lines, vias, and passive components.

3. The method of claim 1 wherein the nanoparticle paste has a viscosity of at least 5,000 cP.

4. The method of claim 1 wherein the nanoparticle paste has a viscosity between 10,000 cP and 5,000,000 cP.

5. The method of claim 1 wherein the stacking comprises precisely aligning the first of the plurality of substrates and the second of the plurality of substrates.

6. The method of claim 1 wherein the plurality of substrates further comprises a third substrate, the third substrate being one of a glass substrate and a ceramic substrate and wherein the method further comprising:
applying a second amount of the conductive nanoparticle paste on at least one of a top surface of the second of the plurality of substrates and a bottom surface of the plurality of substrates;
stacking the third of the plurality of substrates with the second of the plurality of substrates and the first of the plurality of substrates to thereby bond the third of the plurality of the substrates into the stack.

7. The method of claim 1 wherein the nanoparticle paste comprises silver nanoparticles and wherein the method further comprises heating the stack to sinter the silver nanoparticles thereby forming a pure silver interface.

8. The method of claim 1 further comprising laser-micromachining at least one pit in the top surface of the first of the plurality of substrates and placing a glass or ceramic bead in each of the at least one pit to control separation thickness between the first of the plurality of substrates and the second of the plurality of substrates.

9. The method of claim 1 wherein the first amount of the conductive nanoparticle paste is applied to a metallized area on the substrate.

10. The method of claim 1 wherein the first amount of the conductive nanoparticle paste is applied to a non-metallized area on the substrate to assist in maintaining separation between the first of the plurality of the substrates and the second the plurality of substrates.

11. The method of claim 1 further comprising measuring pressure associated with a pick and place machine used when stacking the first of the plurality of substrates and the second of the plurality of substrates.

12. The method of claim 1 wherein the stacking is performed using a pick and place machine and wherein the pick and place machine applies both heat and pressure.

13. The method of claim 1 further comprising sealing edges of the plurality of substrates using at least one of a nanoparticle paste and a ceramic paste.

14. The method of claim 1 further comprising creating holes in at least one of the plurality of substrates to allow for outgassing during the sintering.

15. The method of claim 14 further comprising applying a vacuum, sealing holes in atop layer in the vacuum, and heating to provide a hermetic seal.

16. The method of claim 1 wherein the sintering is provided by heating using directed energy and without an oven.

17. The method of claim 1 further comprising integrating bulk connectors by printing or patterning nanopaste onto pads and adding dielectric adhesive for mechanical stability.

18. The method of claim 1 further comprising using a plurality of sensors during the fabricating to acquire data comprising at least one of temperature, humidity, air quality and vibration.

19. The method of claim 18 further comprising analyzing the data to provide real-time evaluation.

20. The method of claim 18 further comprising generating a digital twin of the microelectronics package using the data.

21. The microelectronics package fabricated according to the method of claim 1.

22. A method for fabricating a microelectronic package, comprising:
providing a plurality of substrates, each being one of a glass substrate and a ceramic substrate;
applying a first amount of conductive nanoparticle paste on at least one of a top surface of a first substrate and a bottom surface of a second substrate;
stacking the first and second substrates such that the top surface of the first substrate bonds with the bottom surface of the second substrate to form a stack; and
sintering the first amount of the conductive nanoparticle paste to provide both electrical and mechanical bonding between the first and second substrates.

23. The method of fabricating a microelectronic package of claim 22, wherein the conductive nanoparticle paste comprises silver nanoparticles, which sinter at a temperature lower than the melting point of the formed silver, thus avoiding reflow and maintaining structural integrity during subsequent heating cycles.

24. The method of fabricating a microelectronic package of claim 22, further comprising:
laser micromachining pits into the substrate surfaces;
placing glass or ceramic beads into the pits to control separation thickness between the substrates;
applying a conductive nanoparticle paste to the surfaces and aligning the substrates with precision using a pick and place machine, which also applies heat and pressure during the stacking process.

25. The method of fabricating a microelectronic package of claim 22, further comprising:
integrating IoT sensors to monitor real-time parameters such as temperature, humidity, air quality, and vibration during the stacking and sintering process;
analyzing the sensor data to provide real-time feedback and control to ensure the quality and consistency of the microelectronic package.

26. The method of fabricating a microelectronic package of claim 22, wherein the process further includes:
laser drilling holes in the substrate to create vias;
filling the drilled holes with a conductive nanoparticle paste and sintering to form electrical connections through the vias; and
patterning additional layers of nanopaste to create metallized conductive lines and components on the substrates.

27. The method of fabricating a microelectronic package of claim 22, further comprising:
creating outgassing holes in the substrates to manage trapped gases during sintering;
applying a vacuum and sealing the holes while under vacuum, followed by heating to achieve a hermetic seal for the microelectronic package.
